(19) United States
(12) Patent Application Publication
(10) Pub. No.: US 2011/0133206 A1
(43) Pub. Date: Jun. 9, 2011

(54) Compound semiconductor device

(75) Inventors: Masahito Kanamura, Kawasaki (JP); Masahiro Nishi, Yamanashi (JP)

(73) Assignees: FUJITSU LIMITED, Kawasaki (JP); EUDYNA DEVICES, INC., Yamanashi (JP)

(21) Appl. No.: 12/929,689

(22) Filed: Feb. 9, 2011

Related U.S. Application Data
(62) Division of application No. 11/295,556, filed on Dec. 7, 2005.

(30) Foreign Application Priority Data
Jan. 14, 2005 (JP) 2005-007966

(51) Int. Cl. H01L 29/12

(52) U.S. Cl. 257/76; 257/E29.068

(57) ABSTRACT

At a gate electrode formed on a compound semiconductor layer with a Schottky junction, a diffusion preventing layer made of TiₓW₁₋ₓN (0<x<1) for suppressing the metal of a low-resistance metal layer from diffusing to the compound semiconductor layer is provided between a Ni layer forming a Schottky barrier with the compound semiconductor layer and the low-resistance metal layer, and thus an increase in the leak current at the gate electrode is suppressed.

### CROSS-REFERENCE TO RELATED APPLICATIONS

This application is based upon and claims the benefit of priority from the prior Japanese Patent Application No. 2005-007966, filed on Jan. 14, 2005, the entire contents of which are incorporated herein by reference.

### BACKGROUND OF THE INVENTION

1. Field of the Invention

The present invention relates to a compound semiconductor device with a high electron mobility transistor (HEMT) structure and a method for manufacturing the same.

2. Description of the Related Art

Recently, the development of a compound semiconductor device with an HEMT structure having a GaN layer as an electron transport layer by utilizing a hetero junction between GaN and Al_{y}Ga_{1-y}N (0<y<1) is actively in progress. The GaN is a material having characteristics that the band gap is wide, the breakdown electric field strength is high, the saturated electron velocity is high, etc, therefore is preferably applicable as a material for a high-voltage operation device and a high-power device. Currently, operations at a high voltage equal to or higher than 40V are required for a power device for a mobile phone base station and the HEMT to which the GaN is applied is highly expected as the power device.

[Patent Document 1] Japanese Patent Application Laid-open No. 2002-359256

For the power device operating at a high voltage as described above, in order to carry out a long-term stable operation even under high-temperature conditions, it is absolutely necessary to suppress an increase in the leak current at a gate electrode. However, in a conventional HEMT, if an operation was carried out for a long term under high-temperature conditions, it was difficult to carry out a stable operation at a high voltage because of an increase in the leak current at a gate electrode.

### SUMMARY OF THE INVENTION

The present invention has been developed the above-mentioned problem being taken into account, and an object thereof is to provide a compound semiconductor device capable of realizing a stable operation at a high voltage for a long term by suppressing an increase in the leak current at a gate electrode and a method for manufacturing the same.

The compound semiconductor device of the present invention has a compound semiconductor layer and an electrode with a Schottky junction on the compound semiconductor layer, and the electrode includes a TiWN layer made of TiₓW₁₋ₓN (0<x<1) and a low-resistance metal layer formed on the TiWN layer.

A compound semiconductor device in another aspect of the present invention has a compound semiconductor layer and an electrode formed on the compound semiconductor layer via a Schottky junction, and the electrode includes a first metal layer made of one kind of metal selected from a group consisting of Ni, Ti, and Ir on the compound semiconductor layer, a second metal layer made of a low-resistance metal, and a third metal layer made of Pd formed between the first metal layer and the second metal layer.

A compound semiconductor device in another aspect of the present invention has a compound semiconductor layer and an electrode formed on the compound semiconductor layer via a Schottky junction, and the electrode includes a low-resistance metal layer and a diffusion preventing layer provided between the low-resistance metal layer and the compound semiconductor layer for suppressing the metal of the low-resistance metal layer from diffusing.

### BRIEF DESCRIPTION OF THE DRAWINGS

FIG. 1 is a schematic sectional view of a compound semiconductor device with a general HEMT structure.

FIGS. 2A to 2C are schematic sectional views of a compound semiconductor device for explaining the fundamental essentials of the present invention.

FIGS. 3A and 3B are schematic sectional views of a compound semiconductor device showing a comparative example.

FIGS. 4A and 4B are schematic sectional views showing a method for manufacturing a compound semiconductor device with an HEMT structure according to a first embodiment in order of process.

FIGS. 5A and 5B are schematic sectional views showing the method for manufacturing a compound semiconductor device with an HEMT structure according to the first embodiment in order of process, following FIGS. 4A to 4B.

FIGS. 6A and 6B are schematic sectional views showing a method for manufacturing a compound semiconductor device with an HEMT structure according to a second embodiment in order of process.

FIGS. 7A and 7B are schematic sectional views showing a method for manufacturing a compound semiconductor device with an HEMT structure according to a third embodiment in order of process.

### DETAILED DESCRIPTION OF THE PREFERRED EMBODIMENTS

### Basic Gist of the Present Invention

The inventors of the present invention have thought out the fundamental essentials of the present invention as follows in order to provide a compound semiconductor device capable of realizing a stable high-voltage operation for a long term by suppressing an increase in the leak current at a gate electrode and a method for manufacturing the same.

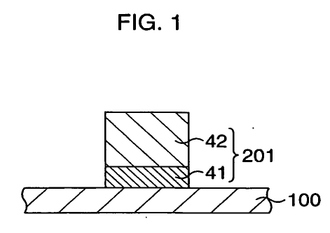

As shown in FIG. 1, a general compound semiconductor device with an HEMT structure having a hetero junction of GaN/Al_{y}Ga_{1-y}N (0<y<1) forms a gate electrode 201 on a compound semiconductor layer 100 made of GaN or Al_{y}Ga_{1-y}N (0<y<1) by providing a metal having a large work function, such as a Ni layer Al, capable of forming a sufficient height (potential) of a Schottky barrier from the compound semiconductor layer and further providing a low-resistance metal layer 42 such as Au on the Ni layer 41 (for example, refer to Patent Document 1).

The general compound semiconductor device has brought about a problem that the leak current at the gate electrode 201 increases. Then, the inventors of the present invention have focused on this point and have considered the fact that due to the use under high-temperature conditions, the metal of the low-resistance metal layer 42 gradually diffuses to the inside of the Ni layer 41 forming a Schottky junction with the compound semiconductor layer 100 and when it finally reaches the boundary surface with the compound semiconductor layer 100, the height of the Schottky barrier is reduced as a result and the leak current at the gate electrode 201 is caused to increase. Therefore, the inventors of the present invention have thought up an idea to provide a diffusion preventing layer for suppressing the metal of the low-resistance metal layer from diffusing between the compound semiconductor layer and the low-resistance metal layer in order to suppress an increase in the leak current at the gate electrode.

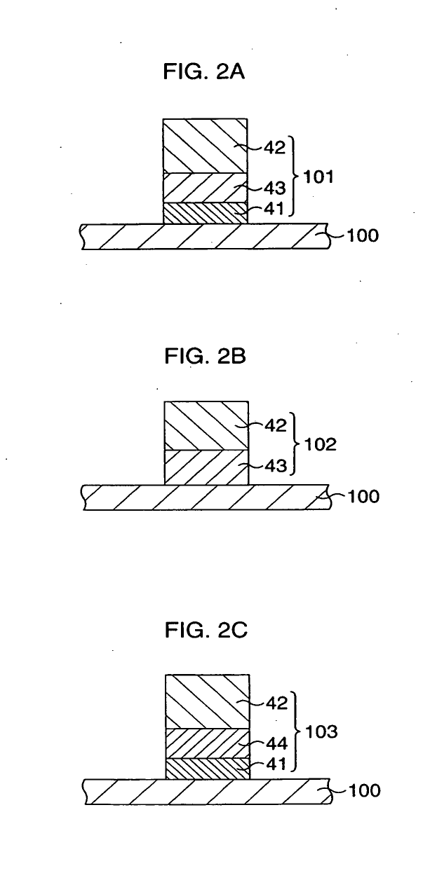

FIGS. 2A to 2C are schematic sectional views of the compound semiconductor device for explaining the fundamental essentials of the present invention. Here, in order to explain the fundamental essentials, only the essential parts of the compound semiconductor device are explained. As shown in FIG. 2A, in the compound semiconductor device according to the present invention, a gate electrode 101 is formed on the compound semiconductor layer 100 made of GaN or Al_{y}Ga_{1-y}N (0<y<1) by sequentially laminating the Ni layer 41 forming a Schottky junction with the compound semiconductor layer 100, a TiₓW₁₋ₓN (0<x<1) layer 43, and the low-resistance metal layer 42.

The inventors of the present invention have focused on the extremely excellent thermal stability of TiₓW₁₋ₓN and the fineness when a film is formed and have made an attempt to provide this as a diffusion preventing layer between the compound semiconductor layer 100 and the low-resistance metal layer 42. Then, due to the TiₓW₁₋ₓN layer 43, it is possible to suppress the metal of the low-resistance metal layer 42 from diffusing to the compound semiconductor layer 100, to stably maintain the height of the Schottky barrier between the compound semiconductor layer 100 and the Ni layer 41, and to suppress an increase in the leak current at the gate electrode.

Further, the inventors of the present invention have found the fact that the TiₓW₁₋ₓN has a work function capable of forming a sufficient height of the Schottky barrier between the compound semiconductor layer 100 and itself when carrying out a high-voltage operation and have thought up an idea to apply this to a compound semiconductor device. A schematic sectional view of the compound semiconductor device is shown in FIG. 2B.

As shown in FIG. 2B, in the compound semiconductor device according to the present invention, a gate electrode 102 is formed on the compound semiconductor layer 100 made of GaN or Al_{y}Ga_{1-y}N by sequentially laminating the TiₓW₁₋ₓN layer 43 and the low-resistance metal layer 42. At this time, the TiₓW₁₋ₓN layer 43 functions as a diffusion preventing layer for suppressing the metal of the low-resistance metal layer 42 from diffusing to the compound semiconductor layer 100 and at the same time, has a function of forming a Schottky junction between the compound semiconductor layer 100 and itself. Due to this, also at the gate electrode 102 having a two-layer structure of the TiₓW₁₋ₓN layer 43 and the low-resistance metal layer 42, it is possible to maintain a stable height of the Schottky barrier between the compound semiconductor layer 100 and itself and to suppress an increase in the leak current at the gate electrode.

Further, the inventors of the present invention have found that Pd having an extremely excellent thermal stability similar to the TiₓW₁₋ₓN described above can be applied as a diffusion preventing layer for suppressing the metal of the low-resistance metal layer 42 from diffusing to the compound semiconductor layer 100. A schematic sectional view of the compound semiconductor device is shown in FIG. 2C.

As shown in FIG. 2C, in the compound semiconductor device according to the present invention, a gate electrode 103 is formed on the compound semiconductor layer 100 made of GaN or Al_{y}Ga_{1-y}N by sequentially laminating the Ni layer 41 forming a Schottky junction with the compound semiconductor layer 100, a Pd layer 44, and the low-resistance metal layer 42.

As described above, the Pd layer 44 has an excellent thermal stability, therefore, it is possible to suppress the metal from diffusing from the low-resistance metal layer 42 formed on the upper to the compound semiconductor layer 100 even in the use under high-temperature conditions. The compound semiconductor device shown in FIG. 2C has a structure in which the Ni layer 41 capable of forming a sufficient height of a Schottky barrier between the compound semiconductor layer and itself is provided on the compound semiconductor layer 100 and the Pd layer 44 is provided on the Ni layer 41 for suppressing the metal of the low-resistance metal layer 42 formed in the uppermost layer from diffusing to the compound semiconductor layer 100.

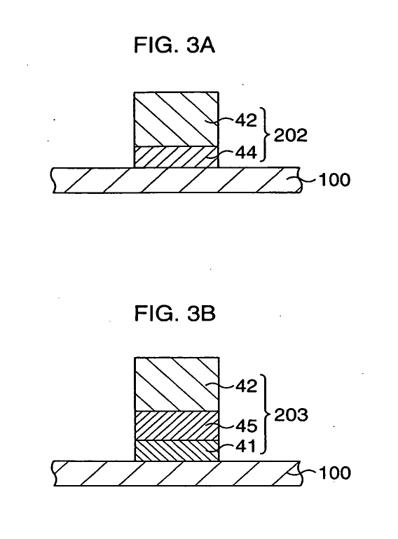

Concerning this point, similar to the compound semiconductor device shown in FIG. 2B, a compound semiconductor device may be possible in which the Pd layer 44, which serves as a diffusion preventing layer, is formed on the compound semiconductor layer 100. In other words, as shown in FIG. 3A, a gate electrode 202 is formed by sequentially laminating the Pd layer 44 and the low-resistance metal layer 42 on the compound semiconductor layer 100. However, at the gate electrode 202, the compound semiconductor layer 100 made of GaN or Al_{y}Ga_{1-y}N (0<y<1) and the Pd layer 44 formed immediately thereon react interactively and as a result, the height of the Schottky barrier that occurs between the compound semiconductor layer 100 and the Pd layer 44 is reduced, therefore, it is not possible to suppress an increase in the leak current at the gate electrode 202.

Alternatively, for example, as shown in FIG. 3B, it may be possible to provide a Pt layer 45 as a diffusion preventing layer between the Ni layer 41 and the low-resistance metal layer 42 to form a gate electrode 203. However, the Pt layer 45 is inferior in thermal stability and Pt in the Pt layer 45 diffuses to the Ni layer 41 under high-temperature conditions. Therefore, the Pt layer 45 does not function as a diffusion preventing layer under high-temperature condition's.

As explained above, the simplest configuration that satisfies both the demand to suppress the metal of the low-resistance metal layer from diffusing in order to suppress an increase in the leak current at the gate electrode and the demand to maintain a sufficient height of a Schottky barrier between the gate electrode and the compound semiconductor layer is the compound semiconductor device of the present invention.

### Concrete Embodiments of the Present Invention

The configuration of a compound semiconductor device with an HEMT structure according to embodiments of the present invention is explained below together with a method for manufacturing the same.

### First Embodiment

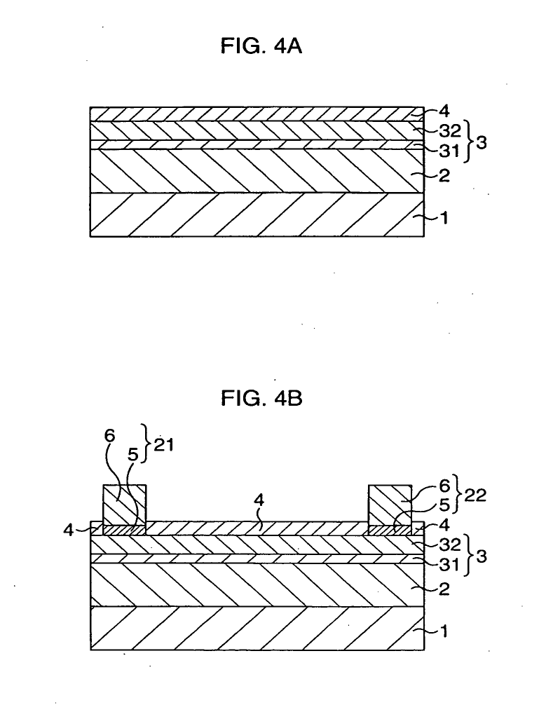

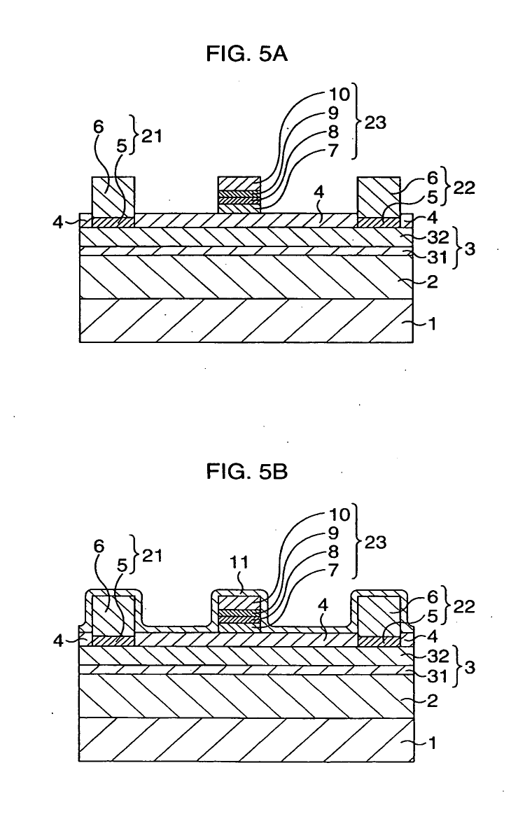

FIGS. 4A to 5B are schematic sectional views showing, in order of process, a method for manufacturing a compound semiconductor device with an HEMT structure according to the first embodiment.

First, as shown in FIG. 4A, on a SiC substrate 1, an i-GaN layer 2, an electron supply layer 3, and an n-GaN layer 4 are laminated sequentially.

Specifically, using the MOVPE method, the intentionally-undoped GaN layer (i-GaN layer) 2, which will be an electron transport layer, is formed on the SiC substrate 1 with a film thickness of about 3 μm. Subsequently, using the MOVPE method, an intentionally-undoped Al_{0.25}Ga_{0.75}N layer (i-Al_{0.25}Ga_{0.75}N layer) 31 is formed on the i-GaN layer 2 with a film thickness of about 3 nm, and further, an n-Al_{0.25}Ga_{0.75}N layer 32 doped with Si at a concentration of about 2×10¹⁸ cm⁻³ is formed with a film thickness of about 20 nm, and thus the electron supply layer 3 having a two-layer structure with these two layers is formed. Next, using the MOVPE method, on the n-Al_{0.25}Ga_{0.75}N layer 32, the n-GaN layer 4 doped with Si at a concentration of about 2×10¹⁸ cm⁻³ is formed with a film thickness of 10 nm or less, for example, a film thickness of about 5 nm.

Here, the electron supply layer 3 is made of the Al_{0.25}Ga_{0.75}N layer, in which the composition ratio y of Al is 0.25 in Al_{y}Ga_{1-y}N, however, the present embodiment is not limited to this and the composition ratio y of Al in the range of 0<y<1 is applicable.

Further, in the present embodiment, the n-GaN layer 4 is a protective layer provided for the purpose of not only stabilizing the I-V characteristics of the compound semiconductor device but also increasing the forward breakdown voltage and the reverse breakdown voltage. In order to cause the n-GaN layer 4 to function as the protective layer described above, it is desirable to set the doping concentration to 2×10¹⁷ cm⁻³ or higher.

Next, as shown in FIG. 4B, the n-GaN layer 4 in the formation regions of the source electrode and the drain electrode is removed, and thus a source electrode 21 and a drain electrode 22 are formed in the respective forming regions.

Specifically, first on the n-GaN layer 4, resist pattern, not shown, which opens at only the formation regions of the source electrode 21 and the drain electrode 22 is formed. Subsequently, by dry etching using chlorine base gases or inactive gases, here, for example, using a cl₂ gas as a chlorine base gas, the n-GaN layer 4 in the formation regions of the source electrode 21 and the drain electrode 22 is removed using the resist pattern as a mask. Next, using the evaporation method, a Ti layer 5 and an Al layer 6 are sequentially laminated on the resist pattern so as to fill the opening with a film thickness of about 20 nm and a film thickness of about 200 nm, respectively.

Next, the Ti layer 5 and the Al layer 6 on the resist pattern are removed at the same time that the resist pattern is exfoliated and removed by the so-called lift-off method and the Ti layer 5 and the Al layer 6 similar to the shape of the opening are left. Then, annealing is carried out at a temperature of about 550° C. to form an ohmic contact between the Ti layer 5 and the n-GaN layer 4 and thus the source electrode 21 and the drain electrode 22 are formed.

Here, in the present embodiment, the n-GaN layer 4 in the formation regions of the source electrode 21 and the drain electrode 22 is removed by dry etching, however, it may be possible to leave a thin layer of the n-GaN layer 4 instead of removing the whole thereof.

Next, as shown in FIG. 5A, a gate electrode 23 is formed on the n-GaN layer 4.

Specifically, first a resist pattern, not shown, which opens at only the formation region of the gate electrode 23 with a width of about 1 μm is formed on the n-GaN layer 4 and the Al layer 6. Subsequently, using the evaporation method, the sputter method, the plating method, etc., a Ni layer 7, a Ti_{0.2}W_{0.8}N layer 8, a TiW layer 9, and a Au layer 10 are sequentially laminated on the resist pattern so as to fill the opening with a film thickness of about 60 nm, 30 nm, 10 nm, and 300 nm, respectively.

Here, in the present embodiment, an example is shown in which Ni is used as a metal material for forming a Schottky junction with the n-GaN layer 4, however, the present embodiment is not limited to this and, for example, Ti or Ir may be applicable. Further, an example is shown in which the n-GaN layer 4 is applied as a compound semiconductor layer for forming a Schottky junction with the gate electrode 23, however, the present embodiment is not limited to this and, for example, Al_{y}Ga_{1-y}N of the same kind as the electron supply layer 3 can be applied as the compound semiconductor layer. In this case, if the composition ratio y in Al_{y}Ga_{1-y}N is in the range of 0<y<1, it can be applied.

Subsequently, the Ni layer 7, the Ti_{0.2}W_{0.8}N layer 8, the TiW layer 9, and the Au layer 10 on the resist pattern are removed at the same time that the resist pattern is exfoliated and removed by the so-called lift-off method, and the Ni layer 7, the Ti_{0.2}W_{0.8}N layer 8, the TiW layer 9, and the Au layer 10 are left in the shape of the opening, and thus the gate electrode 23 is formed. Here, the TiW layer 9 is provided the adhesiveness between the Ti_{0.2}W_{0.8}N layer 8 and the Au layer 10 being taken into account.

Here, the Ti_{0.2}W_{0.8}N layer 8 whose composition ratio x of Ti in TiₓW₁₋ₓN is 0.2 is formed at the gate electrode 23, however, the present embodiment is not limited to this and, if the composition ratio x of Ti is in the range of 0<x<1, it can be applied. At this time, when the composition ratio x of Ti is zero, that is, the layer is a WN layer, there arises a problem that the adhesiveness to the TiW layer 9 formed thereon is degraded.

Next, as shown in FIG. 5B, a SiN film 11 is formed on the entire surface with a thickness of about 10 nm by using the CVD method and the regions between electrodes are covered. After this, through the formation of contact holes for the interlayer insulating film and each electrode and the forming process of various wiring layers etc., the compound semiconductor device with an HEMT structure according to the first embodiment is completed.

According to the compound semiconductor device with an HEMT structure in the first embodiment, since the Ti_{0.2}W_{0.8}N layer 8 having an extremely excellent thermal stability and being a fine film is provided between the Ni layer 7 and the Au layer 10, it is possible to suppress Au from diffusing from the Au layer 10 to the n-GaN layer 4 even under high-temperature conditions and to maintain a stable height of the Schottky barrier between the n-GaN layer 4 and the Ni layer 7. Due to this, it becomes possible to suppress an increase in the leak current at the gate electrode.

### Second Embodiment

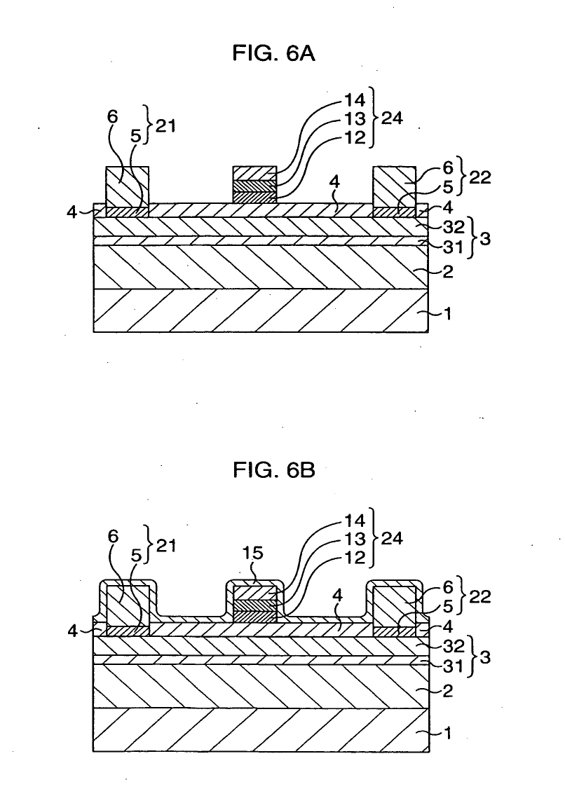

FIGS. 6A and 6B are schematic sectional views showing a method for manufacturing a compound semiconductor device with an HEMT structure according to a second embodiment in order of process.

In the present embodiment, each process shown in FIGS. 4A and 4B is carried out first.

Next, as shown in FIG. 6A, a gate electrode 24 is formed on the n-GaN layer 4.

Specifically, first a Ti_{0.2}W_{0.8}N layer 12 with a film thickness of about 60 nm, a TiW layer 13 with a film thickness of about 40 nm, and a Au layer 14 with a film thickness of about 300 nm are sequentially laminated on the n-GaN layer 4 and the Al layer 6 using the sputter method or the plating method. Then, a resist pattern, not shown, which covers only the formation region of the gate electrode 24 is formed.

Next, the Ti_{0.2}W_{0.8}N layer 12, the TiW layer 13, and the Au layer 14 on the region other than the formation region of the gate electrode 24 are removed by using the resist pattern as a mask by ion milling or dry etching, and the Ti_{0.2}W_{0.8}N layer 12, the TiW layer 13, and the Au layer 14 are left only on the formation region of the gate electrode 24. Then, the resist pattern is removed and thus the gate electrode 24 is formed.

Here, the Ti_{0.2}W_{0.8}N layer 12 whose composition ratio x of Ti in TiₓW₁₋ₓN is 0.2 is formed at the gate electrode 24, however, the present embodiment is not limited to this and, if the composition ratio x of Ti is in the range of 0<x<1, it can be applied. At this time, when the composition ratio x of Ti is zero, that is, the layer is a WN layer, there arises a problem that the adhesiveness to the TiW layer 9 formed thereon is degraded and when the composition ratio x of Ti is 1, that is, the layer is a TiW layer, there arises a problem that the work function becomes small and the height of the Schottky barrier formed between the n-GaN layer 4 and itself is reduced.

Next, as shown in FIG. 6B, a SiN film 15 is formed on the entire surface with a film thickness of about 10 nm by the CVD method and the regions between electrodes are covered. After this, through the formation of contact holes for the interlayer insulating film and each electrode and the forming process of various wiring layers etc., the compound semiconductor device with an HEMT structure according to the second embodiment is completed.

According to the compound semiconductor device with an HEMT structure in the second embodiment, since the Ti_{0.2}W_{0.8}N layer 12 for suppressing Au from diffusing from the Au layer 14 to the n-GaN layer 4 is provided between the n-GaN layer 4 and the Au layer 14, it becomes also possible to form a Schottky barrier between the Ti_{0.2}W_{0.8}N layer 12 and the n-GaN layer 4 and in addition to the effect of the first embodiment described above, the structure of the gate electrode can be further simplified.

### Third Embodiment

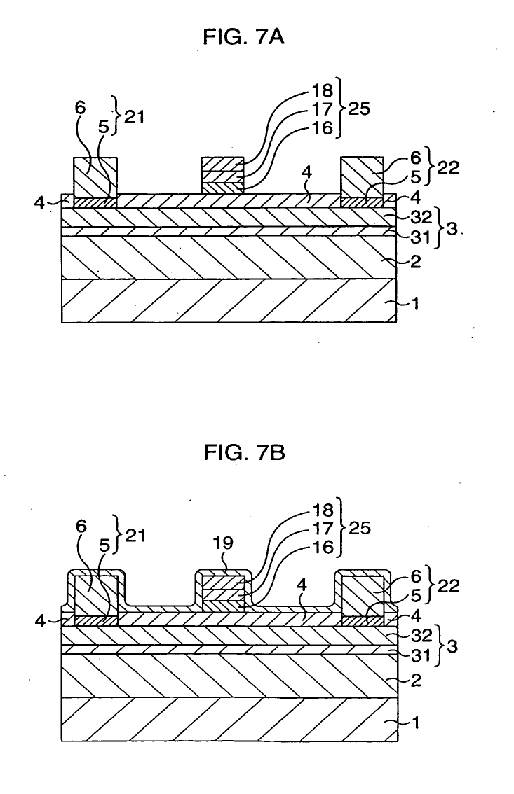

FIGS. 7A and 7B are schematic sectional views showing a method for manufacturing a compound semiconductor device with an HEMT structure according to a third embodiment in order of process.

In the present embodiment, each process shown in FIGS. 4A and 4B′ is carried out first.

Next, as shown in FIG. 7A, a gate electrode 25 is formed on the n-GaN layer 4.

Specifically, first a resist pattern, not shown, which opens only at the formation region of the gate electrode 25 is formed on the n-GaN layer 4 and the Al layer 6 with a width of about 1 μm. Then, a Ni layer 16, a Pd layer 17, and an Au layer 18 are sequentially laminated with a film thickness of about 60 nm, 40 nm, and 300 nm, respectively, on the resist pattern so as to fill the opening by the evaporation method or the sputter method.

Next, the Ni layer 16, the Pd layer 17, and the Au layer 18 on the resist pattern are removed at the same time that the resist pattern is exfoliated and removed by the so-called lift-off method, and the Ni layer 16, the Pd layer 17, and the Au layer 18 are left in the shape of the opening and thus the gate electrode 25 is formed. Here, in the present embodiment, unnecessary heat treatment is not carried out when forming the gate electrode 25 and the Ni layer 16 on the n-GaN layer 4 is formed so as to have a film thickness of about 60 nm, which is sufficiently thick compared to a film thickness of about 10 nm, therefore, no diffusion of Pd is caused from the Pd layer 17 at the boundary surface between the n-GaN layer 4, which is a semiconductor layer, and the Ni layer 16.

Next, as shown in FIG. 7B, a SiN film 19 is formed on the entire surface with a film thickness of about 10 nm by using the CVD method and the regions between electrodes are covered. After this, through the formation of contact holes for the interlayer insulating film and each electrode and the forming process of various wiring layers etc., the compound semiconductor device with an HEMT structure according to the third embodiment is completed.

According to the compound semiconductor device with an HEMT structure in the third embodiment, since the Pd layer 17 having an extremely excellent thermal stability is provided between the Ni layer 16 and the Au layer 18, it is possible to suppress Au from diffusing from the Au layer 18 to the n-GaN layer 4 even under high-temperature conditions and to maintain a stable height of a Schottky barrier between the n-GaN layer 4 and the Ni layer 16. Due to this, it becomes possible to suppress an increase in the leak current at the gate electrode.

The following appendixes are also included in the aspects of the present invention.

(appendix 1) A method for manufacturing a compound semiconductor device comprising:

a process for forming a compound semiconductor layer above a substrate;

a process for forming a TiWN layer made of TiₓW₁₋ₓN (0<x<1) on said compound semiconductor layer with a Schottky junction with said compound semiconductor layer; and

a process for forming a low-resistance metal layer above said TiWN layer.

(appendix 2) The method for manufacturing a compound semiconductor device according to appendix 1, wherein said low-resistance metal layer is made of one kind of metal selected from a group consisting of Au, Cu, and Al.

(appendix 3) A method for manufacturing a compound semiconductor device comprising:

a process for forming a compound semiconductor layer above a substrate;

a process for forming a metal layer made of one kind of metal selected from a group consisting of Ni, Ti, and Ir on said compound semiconductor layer with a Schottky junction with said compound semiconductor layer;

a process for forming a TiWN layer made of TiₓW₁₋ₓN (0<x<1) above said metal layer; and

a process for forming a low-resistance metal layer above said TiWN layer.

(appendix 4) The method for manufacturing a compound semiconductor device according to appendix 3, wherein said low-resistance metal layer is made of one kind of metal selected from a group consisting of Au, Cu, and Al.

(appendix 5) A method for manufacturing a compound semiconductor device comprising:

a process for forming a compound semiconductor layer above a substrate;

a process for forming a metal layer made of one kind of metal selected from a group consisting of Ni, Ti, and Ir on said compound semiconductor layer with a Schottky junction with said compound semiconductor layer;

a process for forming a Pd layer above said metal layer; and

a process for forming a low-resistance metal layer above said Pd layer.

(appendix 6) The method for manufacturing a compound semiconductor device according to appendix 5, wherein said low-resistance metal layer is made of one kind of metal selected from a group consisting of Au, Cu, and Al.

According to the present invention, it is possible to realize a stable high-voltage operation for a long term by suppressing an increase in the leak current at the gate electrode.

1-5. (canceled)

6. A compound semiconductor device comprising:
a compound semiconductor layer; and
an electrode formed on said compound semiconductor layer with a Schottky junction, wherein
said electrode comprises:
a first metal layer made of one kind of metal selected from a group consisting of Ni, Ti, and Ir on said compound semiconductor layer;
a second metal layer made of a low-resistance metal; and
a third metal layer made of Pd formed between said first metal layer and said second metal layer.

7. The compound semiconductor device according to claim 6, wherein said second metal layer is made of one kind of metal selected from a group consisting of Au, Cu, and Al.

8. The compound semiconductor device according to claim 6, further comprising:
an electron transport layer made of GaN; and
an electron supply layer made of Al_{y}Ga_{1-y}N (0<y<1) on said electron transport layer, wherein said compound semiconductor layer is formed on said electron supply layer and made of n-type GaN doped at a concentration of 2×10¹⁷ cm⁻³ or higher.

9-10. (canceled)
